(19) United States
(12) Patent Application Publication
(10) Pub. No.: US 2025/0280627 A1
(43) Pub. Date: Sep. 4, 2025

(54) METHODS FOR LED TRANSFER IN MICRO-LED DISPLAYS

(71) Applicant: Google LLC, Mountain View, CA (US)

(72) Inventor: Jürgen Burggraf, Schaerding (AT)

(21) Appl. No.: 18/595,027

(22) Filed: Mar. 4, 2024

Related U.S. Application Data
(60) Provisional application No. 63/595,950, filed on Nov. 3, 2023.

(51) Int. Cl. H01L 33/00; H01L 25/075; H01L 27/15

(52) U.S. Cl. CPC H10H 20/018; H01L 25/0753; H10H 29/142; H10H 20/0364

(57) ABSTRACT

Fabricating a micro light emitting diode (micro-LED) display may include transferring micro-LEDs from a growth substrate to a two-dimensional array on a back-plane substate. The two-dimensional array on the back-plane substrate has a spacing between micro-LEDs, which is larger than the spacing between micro-LEDs on the growth substrate.

### FIELD OF THE DISCLOSURE

The present disclosure relates to transferring light emitting diodes (LEDs) between substrates to fabricate a micro-LED display.

### BACKGROUND

A micro-LED display includes an array of micro-LEDs, where each micro-LED in the array emits light as a pixel of the display. This display technology offers several advantages compared to other display technologies (e.g., OLED, LCD). For example, because each pixel (i.e., micro-LED) is controllable to emit light (ON) or not emit light (OFF) the contrast ratio can be extremely high (e.g., infinite). Each pixel can be configured to emit a color so no filtering is required to obtain the primary colors of a color. The response time of the pixels can be very fast and their efficiency can be high. Accordingly, the micro-LED displays may have a higher bandwidth and may be brighter than other display technologies.

### SUMMARY

Micro-LEDs can be grown on a growth substrate in a first two-dimensional array with a first pitch (i.e., first period). Select micro-LEDs of the first two-dimensional array may be transferred to a backplane wafer to form a second two-dimensional array with a second pitch. The second pitch can be larger than the first pitch so this transfer process may be repeated to form multiple micro-LED arrays from the same growth substrate.

In some aspects, the techniques described herein relate to a method for fabricating a micro-LED display, the method including: growing a two-dimensional array of LEDs on a growth substrate, the two-dimensional array having LEDs spaced apart by a first pitch; transferring the two-dimensional array of LEDs to a carrier substrate, the two-dimensional array of LEDs held to the carrier substrate by a release layer; bringing together the carrier substrate and a back-plane substrate so that electrical pads of the LEDs at pixel locations of micro-LED display are attached to corresponding bond pads on the back-plane substrate; activating the release layer to generate an activated release layer at the pixel locations of the micro-LED display, wherein the LEDs of the micro-LED display are spaced apart by a second pitch that is greater than the first pitch; and pulling apart the carrier substrate and the back-plane substrate so that the LEDs at the pixel locations of the micro-LED display are transferred from the carrier substrate to the back-plane substrate.

In some aspects, the techniques described herein relate to a method for fabricating a micro-LED display, the method including: growing a two-dimensional array of micro-LEDs on a growth substrate, the two-dimensional array having micro-LEDs spaced apart by a first pitch; transferring the two-dimensional array of micro-LEDs to a carrier substrate, each micro-LED of the two-dimensional array being supported above a cavity in the carrier substrate by a membrane; bringing together the carrier substrate and a back-plane substrate so that electrical pads of the micro-LEDs at pixel locations of micro-LED display are attached to corresponding bond pads on the back-plane substrate; deflecting the membrane at the pixel locations of the micro-LED display to locally release the micro-LEDs from the carrier substrate; and pulling apart the carrier substrate and the back-plane substrate so that the micro-LEDs at the pixel locations of the micro-LED display are transferred from the carrier substrate to the back-plane substrate.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 illustrates a transfer process including pitch scaling to form multiple micro-LED displays from a single substrate according to an implementation of the present disclosure.

FIGS. 2A-2C illustrate steps of an LED transfer process for fabricating an micro-LED display according to a first possible implementation of the present disclosure.

FIGS. 3A-3E illustrate steps of an LED transfer process for fabricating an micro-LED display according to a second possible implementation of the present disclosure.

FIGS. 4A-4B illustrate steps of an LED transfer process for fabricating an micro-LED display according to a third possible implementation of the present disclosure.

The components in the drawings are not necessarily to scale relative to each other. Like reference numerals designate corresponding parts throughout the several views.

### DETAILED DESCRIPTION

Fabricating a micro-LED display may be more expensive than other technologies because of the complex semiconductor processes required to grow small micro-LEDs having a small dimension (e.g., 1 to 10 microns). The fabrication cost can be managed by growing one micro-LED array at a high-density (e.g., pitch <5 micron) on a growth substrate and then using portions of the higher-density micro-LEDs to form different micro-LED arrays on multiple target substrates (i.e., backplane substrates), with each target substrate formed at a lower density (e.g., pitch >5 micron) than the growth substrate (i.e., source substrate).

Detaching the micro-LEDs from the growth substrate and attaching the micro-LEDs to the target substrate is carried out using a process known as LED transfer. LED transfer can be made highly efficient by pressing all micro-LEDs to the target substrate but only detaching/attaching select micro-LEDs. While desirable, this approach faces the technical problem of how to localize the detachment (i.e., release) of the selected micro-LEDs at a scale that is so small. The present disclosure provides methods for localized release of micro-LEDs in an LED transfer process. The methods may be used to fabricate a micro-LED display more simply and with lower fabrication costs than other approaches.

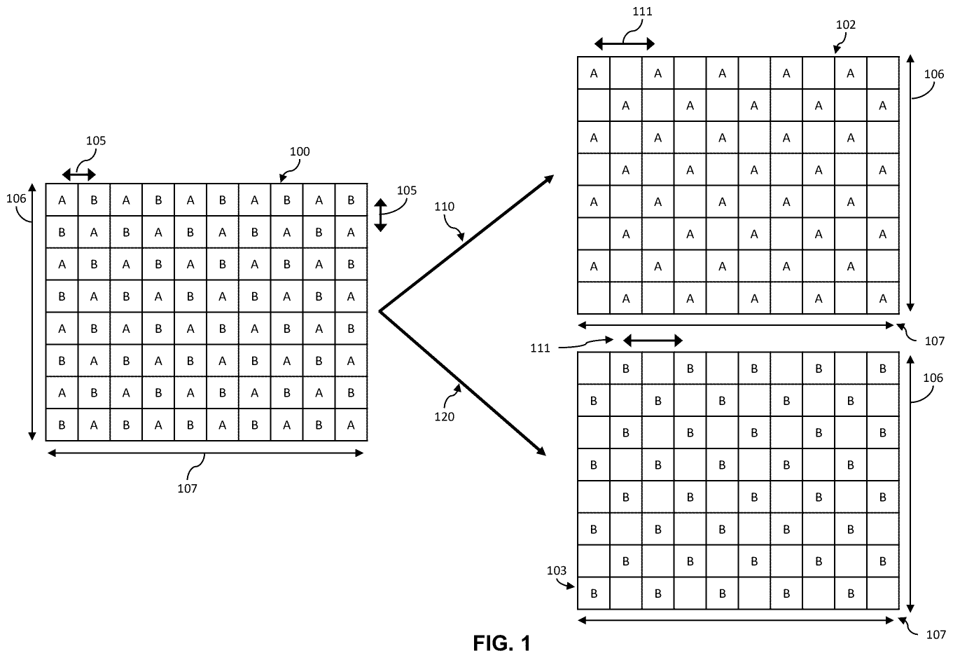

FIG. 1 illustrates a transfer process including pitch scaling to form multiple micro-LED displays from a single substrate according to an implementation of the present disclosure. As shown in this possible implementation, two micro-LED displays can be fabricated from a single substrate.

A growth substrate100 includes a two-dimensional (2D) array of micro-LEDs. Each micro-LED may function as a pixel in a micro-LED display. Accordingly, the micro-LEDs may be configured to generate different colors. For example, the growth substrate 100 may include micro-LEDs configured to generate red light, micro-LEDs configured to generate green light, and micro-LEDs configured to generate blue light as a basis of a full color display. The micro-LEDs may be arranged in the 2D array so that the red (R), blue (B), and green (G) pixels are in a pattern that repeats in either (or both) dimensions. Alternatively, the growth substrate may include micro-LEDs configured to transmit one color (or two colors) in as a basis of a reduced color display. In another possible implementation, the growth substrate 100 may include both a reduced color portion and a full color portion arranged in different areas of the 2D array. Various other spatial arrangements and color combinations can be envisioned to utilize the disclosed techniques.

The 2D array on the growth substrate 100 may be rectangular. The micro-LEDs (i.e., LEDs) on the growth substrate 100 may be spaced apart by a pitch. In one possible implementation, the 2D array can be square with a horizontal dimension 107 and a vertical dimension 106 that are approximately (e.g., ±1%) equal. In another possible implementation, the first vertical pitch and the first horizontal pitch can be approximately (e.g., ±1%) equal. Accordingly, for the purposes of discussion, the horizontal and vertical spacing may be referred to collectively as a first pitch 105.

In a possible implementation, the 2D array is square with each micro-LED in the 2D array on the growth substrate may have a dimension that is in a range between 1 and 10 microns (e.g., 5 microns) and a pitch that is in a range of 1 to 10 microns (e.g., 5 microns). The 2D array may be sized to include more than 10 million micro-LEDs (e.g., 20 M).

The density of the micro-LEDs on the growth substrate 100 may be more than necessary for a micro-LED display. For example, micro-LEDs of the micro-LED display may be spaced apart by 40 microns or more. Accordingly, micro-LEDs may be transferred selectively to create a micro-LED display with pixels that are arranged in a pitch-scaled version of the original 2D array. As a result, the disclosed LED transfer process may be referred to as pitch scaling. FIG. 1 illustrates two LED transfers to create two micro-LED displays, which are each pixel scaled versions of the 2D array on the growth substrate 100.

Prior to transfer, the micro-LEDs in the 2D array may be designated according to the respective layouts of the micro-LED displays. For example, when the pitch scaling is one-half, every odd micro-LED in each row and column may be designated for a first micro-LED display and every even micro-LED in each row and column may be designated for a second micro-LED display. This pitch scaling can be expanded for any number of micro-LED displays. For example, when 3 micro-LED displays are fabricated, the first micro-LED display may use the 1, 4, 7, etc. row/column pixel locations of the 2D array; the second micro-LED display may used the 2, 5, 8, etc. row/column pixel locations of the 2D array, and the third micro-LED display may used the 3, 6, 9, etc. row/column pixel locations of the 2D array. Variations of pitch scaling may be envisioned. For example, alternate rows or areas (e.g., sides) may be used for separate LED transfers.

FIG. 1 illustrates a possible implementation of micro-LED display fabrication using pitch scaling. As shown in FIG. 1, a first group (i.e., A) of micro-LEDs (i.e., LEDs) in the 2D array are designated as pixel locations of a first micro-LED display 102 and a second group (i.e., B) of micro-LEDs in the 2D array are designated as pixel locations of a second micro-LED display 103.

Two LED transfer processes may be carried out. In a first LED transfer process 110, the micro-LEDs of the first group (i.e., A) are transferred from the growth substrate 100 to a first backplane substrate to form a first micro-LED display 102. The first micro-LED display has a vertical dimension 106 and a horizontal dimension 107 that match the growth substrate 100 but the spacing (i.e., second pitch 111) between pixels is larger that the first pitch 105. In a second LED transfer process 120, the micro-LEDs of the second group (i.e., B) are transferred from the growth substrate 100 to a second backplane substrate to form a second micro-LED display 103. The second micro-LED display 103 has a vertical dimension 106 and a horizontal dimension 107 that match the growth substrate 100 but the spacing between pixels (i.e., second pitch 111) is larger than the first pitch 105. The first micro-LED display and the second micro-LED display are substantially the same except for a spatial shift between rows/columns. This shift is small enough (e.g., 5 micrometers (microns)) that it can be imperceptible to a viewer.

The first LED transfer process 110 and the second LED transfer process 120 can be performed in sequence. In other words, the growth substrate 100 can be reused after a first LED transfer for a second LED transfer. In a possible implementation, the growth substrate can be reused until all of the micro-LEDs are all transferred. While two transfer processes are implemented, this process of forming the two micro-LED displays is very efficient because all of the LEDs for each micro-LED display are transferred in their proper position at once. In other words, the growth substrate 100 places the LEDs in the proper position on the back-plane when the two substrates are aligned. Aligning the substrates may be easier than aligning the placement of particular micro-LEDs. This approach requires the ability to transfer select micro-LEDs. For this a localized release mechanism can be used, and in what follows, LED transfer processes using localized release mechanisms will be described.

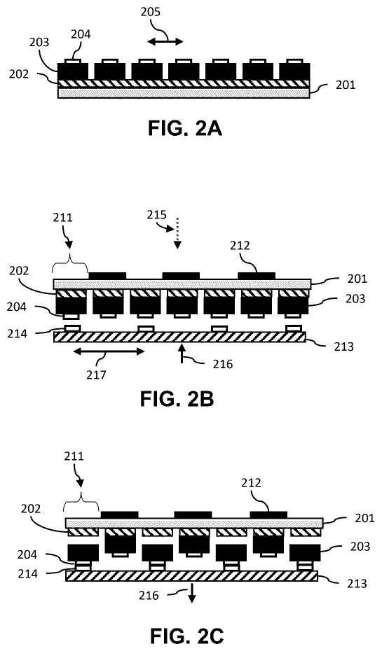

FIGS. 2A-2C illustrate steps of an LED transfer process for fabricating an micro-LED display according to a first possible implementation of the present disclosure. While not shown, the LED's may be grown on a growth substrate. The growth substrate may be silicon. The pixels may be transferred to a handle wafer configured to hold the LEDs so that the growth substrate can be removed. In a possible implementation, the removal includes grinding or spin etching the growth substrate. After the growth substrate is removed, the LEDs may be bonded to a release layer on a surface of a carrier substrate. In a possible implementation, the release layer is an organic or inorganic film deposited on the surface of the carrier substrate via any of the following processes: CVD, PVD, PECVD, MOCVD, spin coating, and spray coating.

FIG. 2A is a side view of a section of a two-dimensional array of micro-LEDs. Each LED is coupled to a carrier substrate 201 (i.e., carrier wafer) via a release layer 202. The LEDs may be different colors. Seven micro-LEDs are shown in FIG. 2A and proceeding from left to right the micro-LEDs may be configured to generate light that is red, green, blue, red, green, blue, red, and so on. The micro-LEDs may be spaced apart on the carrier substrate 201 by a first pitch 205. Each LED has an electrical pad 204 for electrical connection with circuitry of a backplane.

FIG. 2B illustrates the carrier substrate 201 and a back-plane substrate 213 being brought together so each electrical pad 204 of a micro-LED 203 of the display is brought into contact with a corresponding bond pad 214 of a back-plane substrate 213. The bond pads of the back-plane substrate 213 are at pixel locations of the micro-LED display. The pixel locations of the micro-LED display are spaced apart by a second pitch 217. As shown, the second pitch can be larger than the first pitch so that the carrier substrate 201 includes more micro-LEDs than necessary to populate the micro-LED display.

In one possible implementation, the carrier substrate 201 and the back-plane substrate 213 may be brought together by lowering the carrier substrate 201 onto the back-plane substrate 213, or vice versa. In another possible implementation the carrier substrate 201 and the back-plane substrate 213 may be brought together by raising the carrier substrate 201 onto the back-plane substrate, or vice versa. In any case, bringing together the carrier substrate and the back-plane substrate may include creating a compressive force at an interface between the substrates.

As shown in FIG. 2B, prior to bringing together the carrier substrate and the back-plane substrate 213, the release layer 202 may be separated between micro-LEDs. In a possible implementation, the separation is carried out using an etching process. The release layer 202 may be an organic layer, an inorganic layer, or may include a plurality of sublayers.

As shown in FIG. 2B, prior to bringing together the carrier substrate and the back-plane substrate 213, includes applying a mask 212 to a side of the carrier substrate 201 that is opposite to release layer 202. The mask is patterned so that light 215 can be blocked in areas of the mask and unblocked otherwise. In other words, the mask 212 may be an opaque layer having openings 211 aligned with the pixel locations of the micro-LEDs (i.e., aligned with the bond pads of the back-plane substrate 213).

As shown in FIG. 2B, bringing together the carrier substrate and the back-plane substrate 213 may include flipping the carrier substrate 201 so that the electrical pads of the micro-LEDs (at the pixel locations of the micro-LED display) face the corresponding bond pads of the back-plane substrate 213. Further, it may also include aligning the electrical pads of the micro-LEDs and the corresponding bond pads of the back-plane substrate and pressing the electrical pads to the corresponding bond pads to form a bond. Pressing the pads together may include applying a force 216 to either the back-plane substrate 213 or the carrier substrate 201. The bond that is formed between the electrical pads at the pixel locations of the micro-LED display and the corresponding bond pads of the back-plane substrate 213 may be a hybrid bond (i.e., diffusion bond).

After the substrates are brought together, the light 215 may be transmitted to the release layer 202 selectively based on the openings 211 of the mask 212. In a possible implementation the light 215 is scanned over the carrier substrate 201. After being exposed to the light 215, the release layer becomes activated. The activated release layer can have a bond strength that is less than a release layer that has not been exposed to the light 215. Accordingly, micro-LEDs coupled to an activated release layer may be detached from the carrier substrate 201, while micro-LEDs not coupled to an activated release layer may remain attached to the carrier substrate 201. In a possible implementation, the bond strength of the release layer 202 may be reduced by the light 215 through a photochemical or a photothermal process.

As shown in FIG. 2C, the LED transfer process includes pulling apart the carrier substrate 201 and the back-plane substrate 213. For example, the carrier substrate 201 may be raised away from the 213 (or the back-plane substrate 213 may be lowered 216 from the carrier substrate 201) so that the micro-LEDs connected to the activated release layer at the pixel locations of the micro-LED display are transferred to the carrier substrate 213. The transfer results because a bond strength between an electrical pad 204 and a bond pad 214 can be stronger than a bond strength between the micro-LED 203 and the activated release layer.

The micro-LED display includes the backplane substrate and the transferred micro-LEDs. The micro-LEDs on the micro-LED display are at the second pitch 217.

As shown in FIG. 2C, a portion of the micro-LEDs are not transferred to the back-plane substrate and remain attached to the carrier substrate 201. Accordingly, this portion may be used to fabricate a second micro-LED display. For example, the mask 212 may be removed and replaced with a mask configured with openings at pixel locations of the second micro-LED display. For the example shown in FIG. 2C, this second LED transfer may include removing the mask and replacing it with one that includes openings at the remaining micro-LEDs. The remaining micro-LEDs may then be transferred to a second back-plane substrate to form a second micro-LED display.

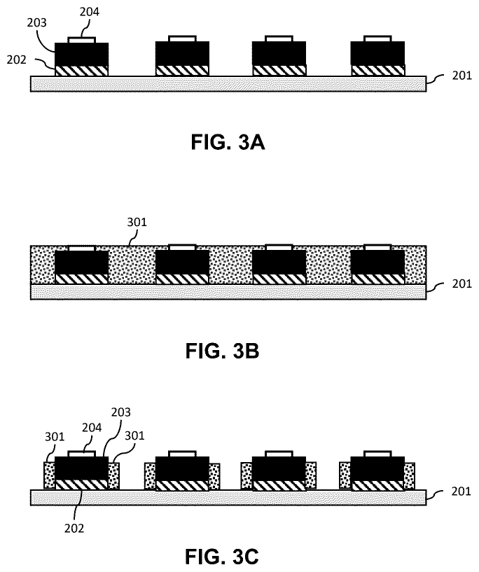

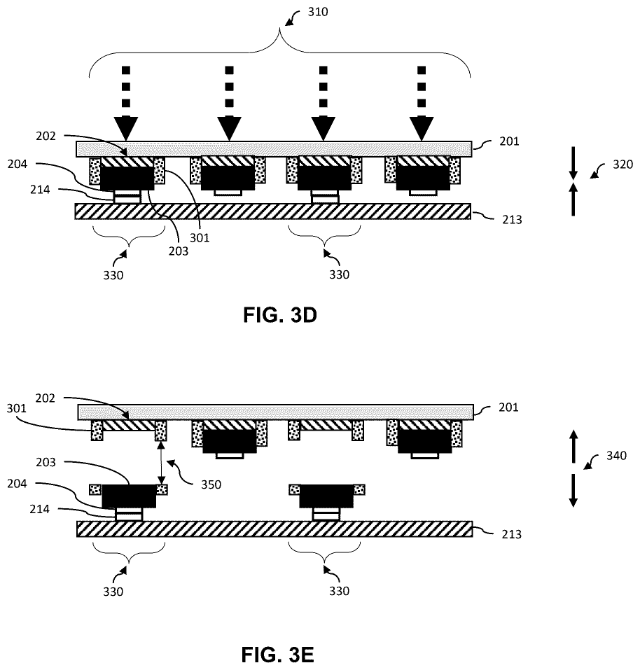

FIGS. 3A-3E illustrate steps of an LED transfer process for fabricating a micro-LED display according to a second possible implementation of the present disclosure. A two-dimensional array of LEDs can be grown on a growth substrate. The growth substrate can be bonded to a handle substrate so the micro-LEDs are between (i.e., sandwiched between) the growth substrate and the handle substrate. The growth substrate may then be removed from the LEDs (e.g., by grinding or etching). After the growth substrate has been removed, the micro-LEDs of the two dimensional array can then be bonded to a carrier substrate and the handle layer may be removed. The carrier substrate includes a release layer that is between the 2D array of LEDs and the carrier substrate. The release layer may be etched between the micro-LEDs so that the release layer is between (i.e., sandwiched between) the dies of the micro-LEDs and a surface (e.g., top surface) of the carrier substrate.

FIG. 3A is a side view of a section of a two-dimensional array of micro-LEDs. Each LED is coupled to a carrier substrate 201 (i.e., carrier wafer) via a release layer 202. As shown, the release layer can be etched to provide separation between the micro-LEDs. Each micro-LED 203 includes an electrical pad 204 configured for electrical interconnection to circuitry of a back-plane substrate.

As shown in FIG. 3B an anchor layer 301 may be deposited around (e.g. covering) the micro-LEDs. In other words, after depositing the anchor layer 301, the micro-LEDs may be embedded (e.g., encapsulated) in the anchor layer 301. The anchor layer may be an organic or inorganic film deposited via CVD, PVD, PECVD, MOCVD, spin coating, or spray coating.

As shown in FIG. 3C, after the anchor layer 301 is deposited, portions can be removed so that only a thin portion of the anchor surrounding each micro-LED 203 remains. The remaining anchor layer 301 at each micro-LED is configured to hold the micro-LED 203 in place after the release layer 202 of the micro-LED 203 is activated. In other words, the anchor layer 301 may adhere to the sides of the micro-LEDs and to a surface (e.g., top surface) of the carrier substrate 201. The thickness of the remaining anchor may be adjusted by the etching. As shown in FIG. 3C the thickness may be uniform along the sides of the micro-LED 203; however in an alternate implementation, the thickness may be non-uniform along the sides of the micro-LED 203.

As shown in FIG. 3C, the anchor layer 301 holding a micro-LED may be configured to break (i.e., separate) under stress. In other words, the hold on a micro-LED by the anchor layer 301 may be broken by a force. The act of separating (i.e., breaking) the anchor layer may be facilitated by the thickness of the anchor layer 301, which may be less than a dimension of the micro-LED 203 (e.g., thickness <5 microns). The act of separating (i.e., breaking) the anchor layer may also be facilitated by heating the anchor layer 301, which may be a thermoplastic material configured to change properties (e.g., melt) as the temperature of the material is elevated. The separating (i.e., breaking) may also be facilitated by a compressive pressure or a tensile pressure applied to the anchor layer 301.

As shown in FIG. 3D bringing together the carrier substrate 201 and the back-plane substrate 213 may include flipping the carrier substrate 201 so that an electrical pad 204 of a micro-LED at a pixel location of the micro-LED display faces a corresponding bond pad 214 of the back-plane substrate 213. This operation may include aligning the electrical pads of the micro-LEDs and the corresponding bond pads of the back-plane substrate and applying a compressive force 320 to press the electrical pads to the corresponding bond pads to form a bond. The bond that is formed between the electrical pads at the pixel locations of the micro-LED display and the corresponding bond pads of the back-plane substrate 213 may be a hybrid bond (i.e., diffusion bond).

As shown in FIG. 3D, the release layer 202 may be activated by applying activation energy 310 to the release layer 202 through the carrier substrate 201. The activation energy 310 may be heat and/or light. The heat and/or light may be applied generally to all micro-LEDs because after the release layer is activated the micro-LEDs may remain held to the carrier substrate 201 by the anchor layer 301.

As shown in FIG. 3E, the carrier substrate 201 and the back-plane substrate 213 may be separated (e.g., pulled apart) by a force 340 applied to the carrier substrate 201 and/or back-plane substrate 213. The bond between the electrical pad 204 of the micro-LED 203 and the corresponding bond pad 214 of the back-plane substrate 213 may be strong enough to separate 350 (e.g., breaks, cracks, etc.) the anchor layer 301 and pull the micro-LED 203 away from the activated release layer 202 as a result of the applied force 340. In this way, micro-LEDs at the pixel locations 330 of the micro-LED display can be transferred from the carrier substrate 201 to the back-plane substrate 213, while micro-LEDs that are not at the pixel locations 330 of the micro-LED display are not be transferred. The micro-LEDs that are not transferred may be aligned and bonded with corresponding bond pads of a second back-plane substrate for a second LED transfer from the carrier substrate 201 to the second back-plane substrate. This process may be repeated for additional LED transfers based on the layout of the 2D of LEDs on the growth substrate and the layout of the pixel locations on the back-plane substrates. In a possible implementation, the LED transfer operations may be repeated until there no micro-LEDs remain on the carrier substrate 201.

As discussed, LED transfer using localized release may be based on reducing a bond strength of the release layer through a photo-effect or thermal-effect. In an alternative implementation, the localized release may be based on reducing a bond strength through a mechanical deflection 430.

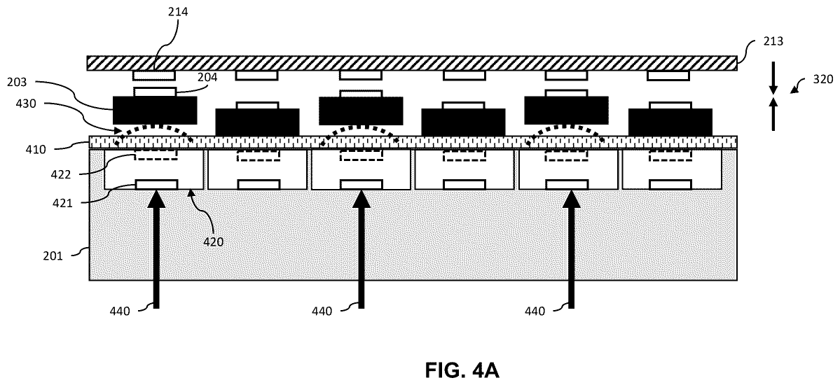

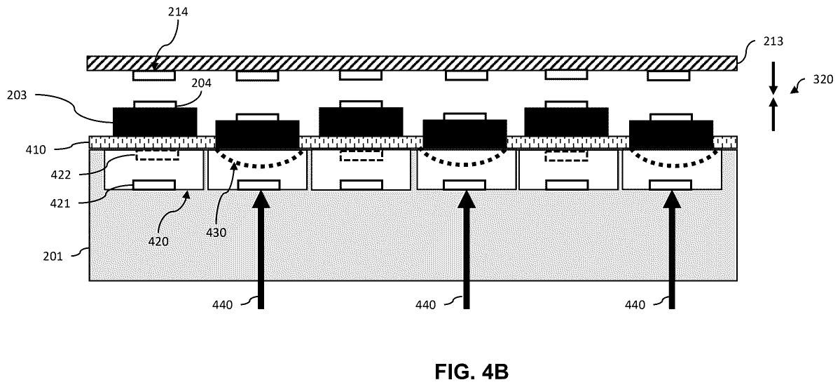

FIGS. 4A-4B illustrates steps of an LED transfer process for fabricating an micro-LED display according to a third possible implementation of the present disclosure.

FIG. 4A illustrates a side-view of a portion of a two-dimensional array of micro-LEDs (i.e., LEDs). The micro-LEDs may be grown on a growth substrate (not shown) and transferred to a carrier substrate 201. The carrier substrate 201 includes a plurality of cavities. Each cavity 420 is positioned adjacent to (e.g., below) a deflectable layer (i.e., membrane 410). Each micro-LED 203 of the 2D array may be on a first surface of the membrane 410. Each cavity 420 may include at least one conductor. For example, the cavity 420 may include a first conductor 421 and a second conductor 422. As shown the first conductor 421 may be located at a bottom portion of the cavity 420 that is further away from the micro-LED 203 than a second conductor 422 located at a top portion of the cavity. In a possible implementation, the second conductor is absent and the cavity includes only the first conductor 421.

As shown in FIG. 4A bringing together the carrier substrate 201 and the back-plane substrate 213 may include aligning the each electrical pad 204 of each micro-LED to each corresponding bond pad 214 of the back-plane substrate 213 and applying a compressive force 320 to press the electrical pads to the corresponding bond pads to form a bond.

As shown in FIG. 4A the membrane 410 may be deflected so that the micro-LEDs at the locations of the micro-LED display are elevated above the undeflected surface of the carrier substrate 201. The elevated micro-LEDs can make contact with the corresponding bond pad for bonding whereas the micro-LEDs at the locations of the undeflected membrane 410 may not make contact with the corresponding bond pad for bonding. After bonding the carrier substrate 201 and the back-plane substrate 213 may be pulled apart with the bonded micro-LEDs connected to the back-plane substrate 213. The deflection 430 shown in FIG. 4A may be referred to as a convex deflection because the surface of the membrane 410 is made to extend outward from a center of carrier substrate 201.

As shown in FIG. 4B the membrane 410 may be deflected so that the micro-LEDs at the locations of the micro-LED display are sunken below the undeflected surface of the carrier substrate 201. The sunken micro-LEDs can not make contact with the corresponding bond pad for bonding whereas the micro-LEDs at the locations of the undeflected membrane 410 may make contact with the corresponding bond pad for bonding. After bonding the carrier substrate 201 and the back-plane substrate 213 may be pulled apart with the bonded micro-LEDs connected to the back-plane substrate 213. The deflection shown in FIG. 4B may be referred to as a concave deflection because the surface of the membrane 410 is made to extend inwards towards the center of carrier substrate 201.

The deflection of the membrane 410 may be carried out using a deflection energy 440 applied locally. In a first possible implementation the deflection energy is light from a laser. The light may be focused onto the first conductor 421 of the cavity 420. The first conductor 421 may be heated by the light to generate a heated cavity. The membranes of be heated cavities can be deflected by an expanding gas in each of the heated cavities.

In a second possible implementation, the deflection energy is an electric field (i.e., electrostatic potential, voltage). The voltage can be applied between the first conductor 421 and the second conductor 422. The voltage can generate an electro-state force between the conductors that push the second conductor 422 away from the first conductor 421 for a convex deflection or that can pull the second conductor 422 towards the first conductor 421 for a concave deflection.

The membrane 410 may be metallic (e.g., copper) and can utilize the construction techniques and designs of a micro-electromechanical system (i.e., MEMS). In a possible implementation the second conductor 422 is the metallic membrane 410.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

What is claimed is:

1. A method for fabricating a micro-LED display, the method comprising:
growing a two-dimensional array of LEDs on a growth substrate, the two-dimensional array having LEDs spaced apart by a first pitch;
transferring the two-dimensional array of LEDs to a carrier substrate, the two-dimensional array of LEDs held to the carrier substrate by a release layer;
bringing together the carrier substrate and a back-plane substrate so that electrical pads of the LEDs at pixel locations of micro-LED display are attached to corresponding bond pads on the back-plane substrate;
activating the release layer to generate an activated release layer at the pixel locations of the micro-LED display; and
pulling apart the carrier substrate and the back-plane substrate so that the LEDs at the pixel locations of the micro-LED display are transferred from the carrier substrate to the back-plane substrate by the activated release layer, wherein the LEDs of the micro-LED display are spaced apart by a second pitch that is greater than the first pitch.

2. The method according to claim 1, where a first bond between a first LED and the activated release layer has a bond strength that is less than a second bond between a second LED and the release layer without activation.

3. The method according to claim 1, wherein a first portion of the two-dimensional array of LEDs are transferred to from the carrier substrate to the back-plane substrate and a second portion of the two-dimensional array of LEDs are not transferred from the carrier substrate to the back-plane substrate.

4. The method according to claim 3, wherein the micro-LED display is a first micro-LED display and the method further comprises:
using the second portion not transferred to the back-plane substrate to fabricate a second micro-LED display.

5. The method according to claim 1, wherein transferring the two-dimensional array of LEDs to the carrier substrate includes:
grinding or spin etching to remove the growth substrate after transferring the two-dimensional array of LEDs to the carrier substrate.

6. The method according to claim 1, wherein the release layer is organic.

7. The method according to claim 1, wherein the release layer is inorganic.

8. The method according to claim 1, wherein the release layer includes a plurality of sublayers.

9. The method according to claim 1, wherein bringing together the carrier substrate and the back-plane substrate includes:
aligning the electrical pads of the LEDs and the corresponding bond pads of the back-plane substrate; and
pressing the electrical pads to the corresponding bond pads to form a bond.

10. The method according to claim 9, wherein activating the release layer to generate the activated release layer at the pixel locations of the micro-LED display includes:
applying a mask to a side of the carrier substrate opposite to the LEDs and the release layer, the mask including openings at the pixel locations of the micro-LED display; and
transmitting light to the mask wherein the mask:
passes the light to the release layer at the openings; and
blocks the light otherwise.

11. The method according to claim 10, wherein pulling apart the carrier substrate and the back-plane substrate includes
transferring the LEDs coupled to the activated release layer to the back-plane substrate, the activated release layer having a bond strength that is less than the bond between the electrical pads and the corresponding bond pads.

12. The method according to claim 1, wherein:
transferring the two-dimensional array of LEDs to the carrier substrate includes:
removing the release layer between LEDs to create a gap between the LEDs;
applying an anchor layer at a thickness sufficient to fill the gap between the LEDs; and
removing portions anchor layer so that each LED of the two-dimensional array of LEDs is encapsulated by the anchor layer; and
bringing together the carrier substrate and the back-plane substrate includes:
flipping the carrier substrate so that the electrical pads of the LEDs at the pixel locations of the micro-LED display face the corresponding bond pads of the back-plane substrate;
aligning the electrical pads of the LEDs and the corresponding bond pads of the back-plane substrate; and
pressing the electrical pads to the corresponding bond pads.

13. The method according to claim 12, wherein activating the release layer to generate an activated release layer at the pixel locations of the micro-LED display includes:
scanning a laser over a side of the carrier substrate opposite to the LEDs to activate the release layer at each LED, wherein after activation, each LED is held to the carrier substrate by the anchor layer encapsulating each LED.

14. The method according to claim 13, wherein pulling apart the carrier substrate and the back-plane substrate so that the LEDs of the micro-LED display are detached from the carrier substrate as a result of a diminished hold strength of the activated release layer at the pixel locations of the micro-LED display includes:
separating the anchor layer that encapsulates LEDs, which are attached to bond pads on the back-plane substrate, so that the LEDs of the micro-LED display are transferred from the carrier substrate to the back-plane substrate; and
not separating the anchor layer that encapsulates LEDs, which are not attached to bond pads on the back-plane substrate so that they are not transferred from the carrier substrate.

15. The method according to claim 14, wherein activating the release layer to generate an activated release layer at the pixel locations of the micro-LED display includes:
applying heat to a side of the carrier substrate opposite to the LEDs and the release layer to activate the release layer at each LED, wherein after activation, each LED is held to the carrier substrate by the anchor layer encapsulating each LED.

16. The method according to claim 15, wherein pulling apart the carrier substrate and the back-plane substrate so that the LEDs of the micro-LED display are detached from the carrier substrate as a result of a diminished hold strength of the activated release layer at the pixel locations of the micro-LED display includes:
separating the anchor layer that encapsulates LEDs, which are attached to bond pads on the back-plane substrate, so that the LEDs of the micro-LED display are transferred from the carrier substrate to the back-plane substrate; and
not separating the anchor layer that encapsulates LEDs, which are not attached to bond pads on the back-plane substrate so that they are not transferred from the carrier substrate.

17. The method according to claim 1, wherein transferring the two-dimensional array of LEDs to the carrier substrate includes:
bonding, at a side opposite the growth substrate, the two-dimensional array of LEDs to a handle substrate;
removing the growth substrate from the two-dimensional array of LEDs; and
bonding the LEDs to the release layer on the carrier substrate in place of the growth substrate.

18. A method for fabricating a micro-LED display, the method comprising:
growing a two-dimensional array of micro-LEDs on a growth substrate, the two-dimensional array having micro-LEDs spaced apart by a first pitch;
transferring the two-dimensional array of micro-LEDs to a carrier substrate, each micro-LED of the two-dimensional array being supported above a cavity in the carrier substrate by a membrane;
bringing together the carrier substrate and a back-plane substrate so that electrical pads of the micro-LEDs at pixel locations of micro-LED display are attached to corresponding bond pads on the back-plane substrate;
deflecting the membrane at the pixel locations of the micro-LED display to locally release the micro-LEDs from the carrier substrate; and
pulling apart the carrier substrate and the back-plane substrate so that the micro-LEDs at the pixel locations of the micro-LED display are transferred from the carrier substrate to the back-plane substrate.

19. The method according to claim 18, wherein deflecting the membrane at the pixel locations of the micro-LED display includes:
heating cavities at the pixel locations of the micro-LED display so that membranes of heated cavities are deflected by an expanding gas in each of the heated cavities.

20. The method according to claim 19, wherein heating cavities at the pixel locations of the micro-LED display includes:
transmitting a laser to cavities at the pixel locations of the micro-LED display to locally heat a metal layer in each of the cavities.

21. The method according to claim 18, wherein deflecting the membrane at the pixel locations of the micro-LED display includes:
applying an electric field to cavities at the pixel locations of the micro-LED display so that membranes of the cavities are deflected by an electrostatic potential.

22. The method according to claim 21, wherein:
each cavity includes a first conductor;
each membrane includes a second conductor; and
the electric field is applied between the first conductor and the second conductor.
